(19) United States
(12) Patent Application Publication
(10) Pub. No.: US 2007/0224756 A1
(43) Pub. Date: Sep. 27, 2007

(54) METHOD FOR FABRICATING RECESSED GATE MOS TRANSISTOR DEVICE

(76) Inventors: Yu-Pi Lee, Taipei County (TW); Shian-Jyh Lin, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/456,856

(22) Filed: Jul. 11, 2006

(30) Foreign Application Priority Data
Mar. 23, 2006 (TW) 095110129

(51) Int. Cl. H01L 21/336; H01L 21/8242

(52) U.S. Cl. 438/243; 438/270; 438/296

(57) ABSTRACT

A method of fabricating self-aligned gate trench utilizing TTO spacer is disclosed. A semiconductor substrate having thereon a pad oxide layer and pad nitride layer is provided. Trench capacitors are formed in a memory array region of the semiconductor substrate. Each of the trench capacitors has a trench top oxide (TTO) that extrudes from a main surface of the semiconductor substrate. Spacers are formed on the extruding TTO and are used, after oxidized, as an etching hard mask for etching a recessed gate trench in close proximity to the trench capacitor.

### BACKGROUND OF THE INVENTION

1. Field of the Invention

The present invention relates generally to a method for fabricating semiconductor devices. More specifically, the present invention relates to a method for making recessed-gate Metal-Oxide-Semiconductor (MOS) transistor of Dynamic Random Access Memory (DRAM) devices.

2. Description of the Prior Art

Integrated circuit devices are continually being made smaller in order to increase speed, make the device more portable and to reduce the cost of manufacturing the device. However, certain designs have a minimum feature size, which cannot be reduced without compromising the integrity of electrical isolation between devices and consistent operation of the device. For example, dynamic random access memory devices (DRAMs), which use vertical metal oxide semiconductor field effect transistors (MOSFETs) with deep trench (DT) storage capacitors, have a minimum features size of approximately 90 nm˜0.15 μm. Below that size, the internal electric fields exceed the upper limit for storage node leakage, which decreases retention time below an acceptable level. Therefore, there is a need for different methods and/or different structures to further reduce the size of integrated circuit devices.

With the continued reduction in device size, sub-micron scale MOS transistors have to overcome many technical challenges. As the MOS transistors become narrower, that is, their channel length decreases, problems such as junction leakage, source/drain breakdown voltage, and data retention time become more pronounced.

One solution to decrease the physical dimension of ULSI circuits is to form recessed gate or “trench-type” transistors, which have a gate electrode buried in a groove formed in a semiconductor substrate. This type of transistor reduces short channel effects by effectively lengthening the effective channel length by having the gate extend into the semiconductor substrate.

The recess-gate MOS transistor has a gate insulation layer formed on sidewalls and bottom surface of a recess etched into a substrate, a conductive filling the recess, contrary to a planar gate type transistor having a gate electrode formed on a planar surface of a substrate.

However, the aforesaid recessed-gate technology has some shortcomings. For example, the recess for accommodating the recessed gate of the MOS transistor is etched into a semiconductor wafer by using conventional dry etching methods. It is difficult to control the dry etching and form recesses having the same depth across the wafer. A threshold voltage (Vt) control problem arises because of recess depth variation. Moreover, the recess lithography to DT (deep trench) overlay may also impact the Vt.

### SUMMARY OF THE INVENTION

It is one object of this invention to provide a method of fabricating a recess-gate MOS transistor of DRAM devices in order to solve the above-mentioned problems.

According to the claimed invention, a method for fabricating a recessed gate MOS transistor device is provided. A semiconductor substrate having a main surface is provided. A pad layer is formed on the main surface. A plurality of trench capacitors is formed in the semiconductor substrate. Each trench capacitor is capped with a trench top oxide layer. The trench top oxide layer has a top surface higher than the main surface. A lithographic and etching process is performed to form a plurality of isolation trenches in the semiconductor substrate. An insulation layer is deposited on the semiconductor substrate and in the isolation trenches. The insulation layer fills the isolation trenches. The insulation layer is etched back such that a top surface of the insulation layer is lower than the top surface of the trench top oxide layer. The pad layer is stripped to expose the semiconductor substrate and the trench top oxide layer. A spacer is formed on sidewalls of the trench top oxide layer. Using the spacer as an etching hard mask, the semiconductor substrate is etched to form a gate trench. A gate dielectric layer is formed on interior surface of the gate trench. A gate material layer is formed on the gate dielectric layer, wherein the gate material layer fills the gate trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic top view showing the layout of the deep trench capacitors in the memory array area according to this invention;

FIGS. 2-22 are schematic, cross-sectional diagrams illustrating an exemplary method of fabricating a recessed-gate MOS transistor in accordance with one preferred embodiment of this invention; and

FIG. 23 is a schematic top view of the structure set forth in FIG. 4.

### DETAILED DESCRIPTION

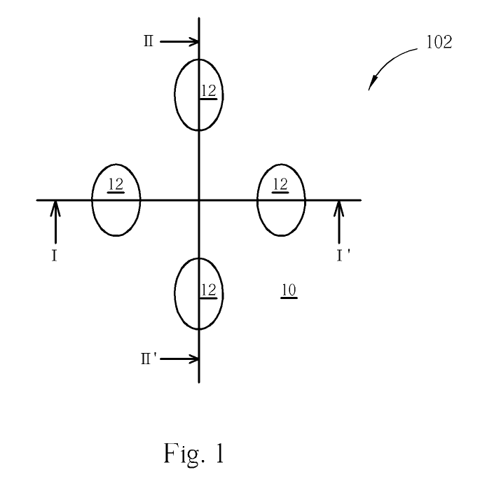

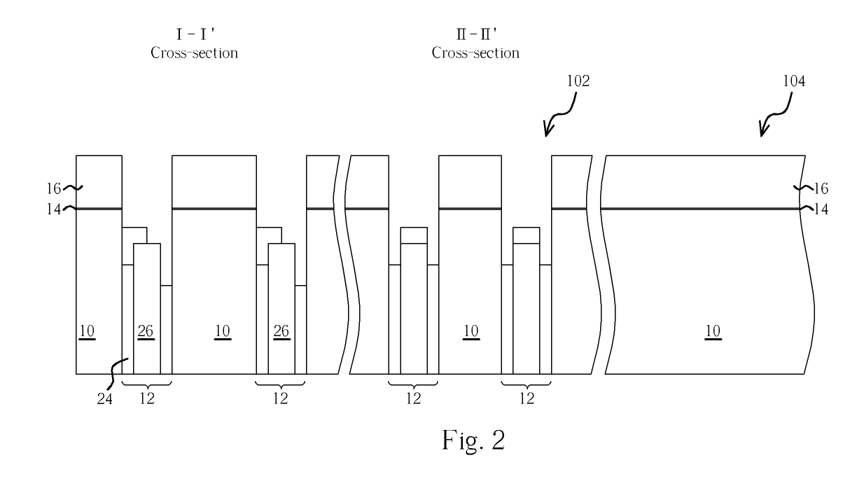

Please refer to FIGS. 1-22. FIG. 1 is a schematic top view showing the layout of the deep trench capacitors in the memory array area according to this invention. FIGS. 2-22 are schematic, cross-sectional diagrams illustrating an exemplary method of fabricating a recessed-gate MOS transistor in accordance with one preferred embodiment of this invention. As shown in FIGS. 1 and 2, a semiconductor substrate 10 having thereon a pad oxide layer 14 and a pad nitride layer 16 is provided. The semiconductor substrate 10 may include but not limited to a silicon substrate, silicon epitaxital substrate or Silicon-On-Insulator (SOI) substrate. Deep trench capacitors 12 are formed within a memory array area 102 of the semiconductor substrate 10. For the sake of clarity, a peripheral circuit area 104 and both of the I-I′ cross section and II-II′ cross section of the memory array area 102 in FIG. 1 are shown in the subsequent drawings.

As shown in FIG. 2, the deep trench capacitor 12 comprises a sidewall capacitor dielectric layer 24 and a doped polysilicon 26. The deep trench capacitor 12 is fabricated using Single-Sided Buried Strap (SSBS) process. The doped polysilicon 26 functions as one electrode of the deep trench capacitor 12. The method for fabricating the deep trench capacitor 12 is known in the art. For the sake of simplicity, only the upper portions of the deep trench capacitor 12 are shown in figures. It is understood that the deep trench capacitor 12 further comprises a buried plate acting as the other capacitor electrode, which is not shown.

The aforesaid SSBS process generally comprises the steps of etching back the sidewall oxide dielectric layer and the doped polysilicon (or so-called Poly-2) 26 to a first depth; refilling the recess with another layer of polysilicon (or so-called Poly-3); etching back the Poly-3 to a second depth; forming an asymmetric spacer on interior sidewall of the recess; etching away the Poly-3 and Poly-2 that are not covered by the asymmetric spacer; filling the recess with TTO insulation layer; and chemical mechanical polishing the TTO insulation layer.

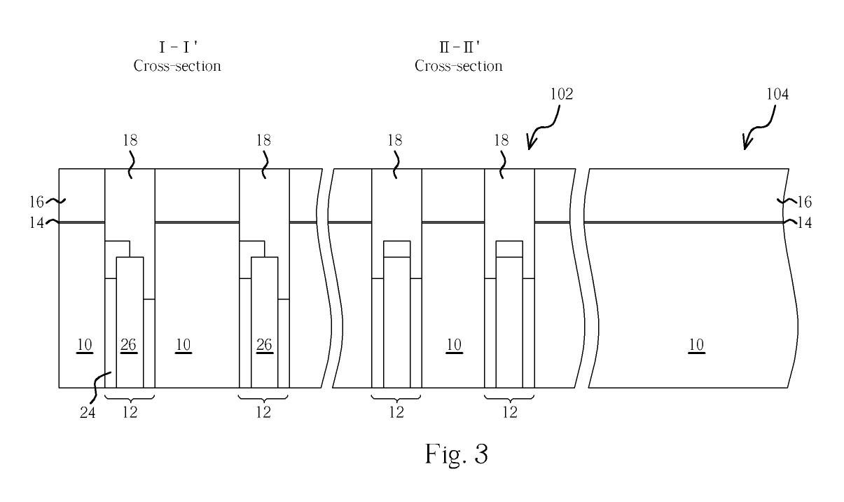

As shown in FIG. 3, a silicon oxide layer is deposited over the semiconductor substrate 10 and fills the recesses on the deep trench capacitors 12. Thereafter, using the pad nitride layer 16 as a polishing stop layer, a chemical mechanical polishing (CMP) process is carried out to planarize the silicon oxide layer, thereby forming a trench top oxide layer 18 on each deep trench capacitor 12.

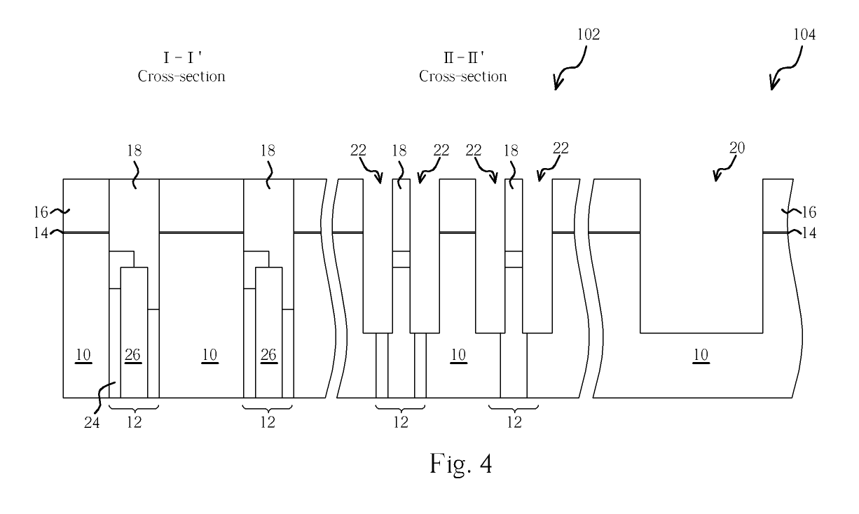

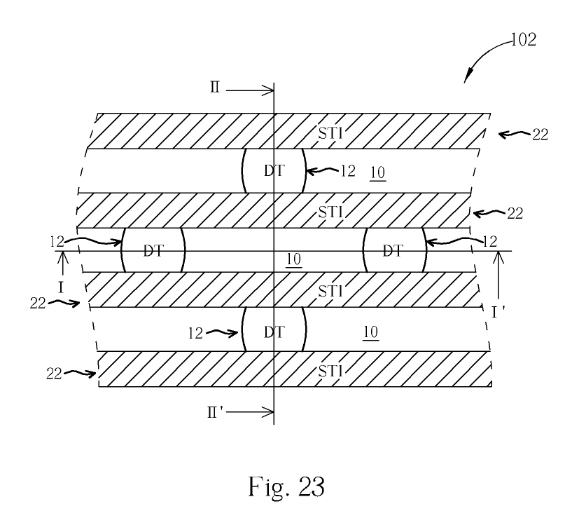

As shown in FIG. 4, subsequently, a shallow trench isolation (STI) process is performed to form STI trenches 22 and 20 in the memory array area 102 and in the peripheral circuit area 104 respectively. FIG. 23 shows a top view of the STI trench structure in FIG. 4.

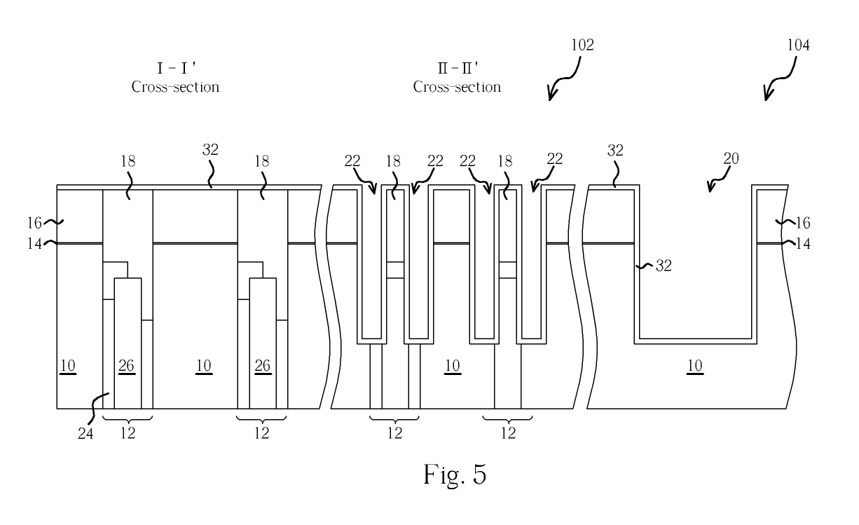

As shown in FIG. 5, a silicon nitride liner 32 is deposited on the semiconductor substrate 10. The silicon nitride liner 32 has a thickness of about 5-150 angstroms. The silicon nitride liner 32 conformally covers the pad nitride layer 16, the trench top oxide layer 18 and the interior surfaces of the STI trenches 22 and 20.

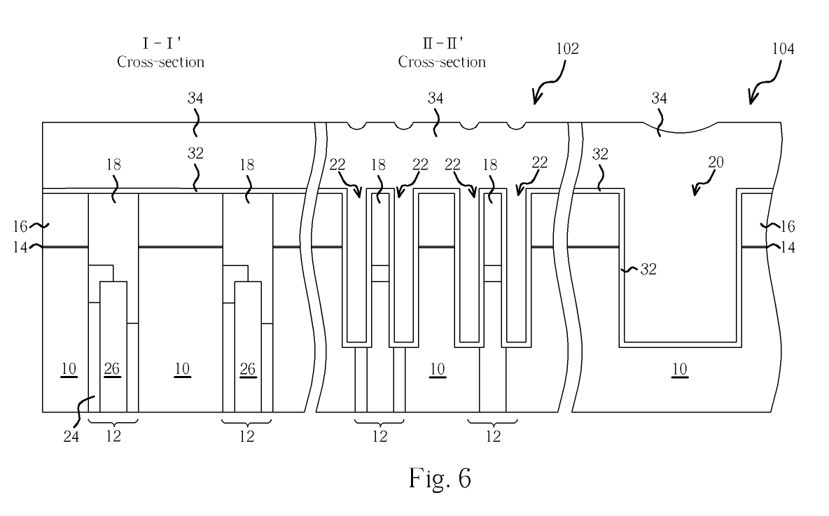

As shown in FIG. 6, after the deposition of the silicon nitride liner 32, a silicon oxide layer 34 is deposited over the semiconductor substrate 10. The silicon oxide layer 34 fills the STI trenches 22 and 20. According to the preferred embodiments, the silicon oxide layer 34 is formed by Chemical Vapor Deposition (CVD) methods such as High-Density Plasma CVD (HDPCVD) process. The STI trenches may not be filled in one step. The STI fill process may include SOG etch back, SiN etch back and oxide fill. The STI fill material may be two or three layers.

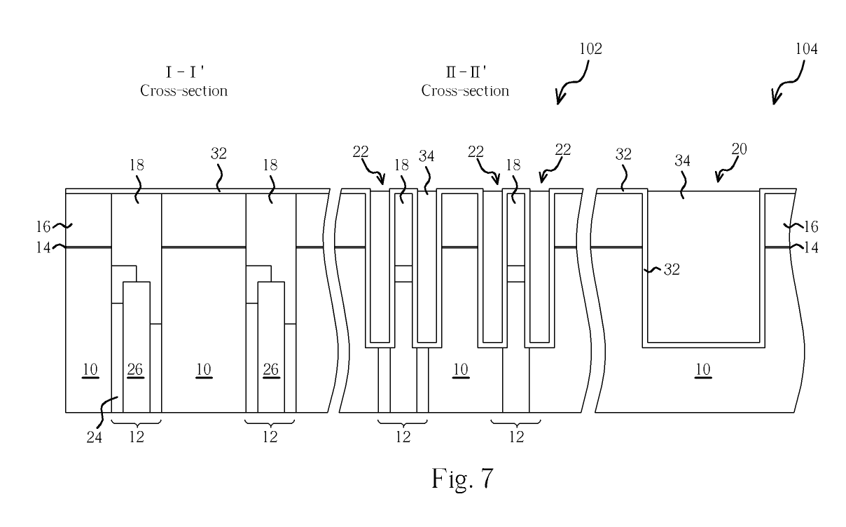

As shown in FIG. 7, using the silicon nitride liner 32 as a polishing stop layer, a CMP process is performed to planarize the silicon oxide layer 34.

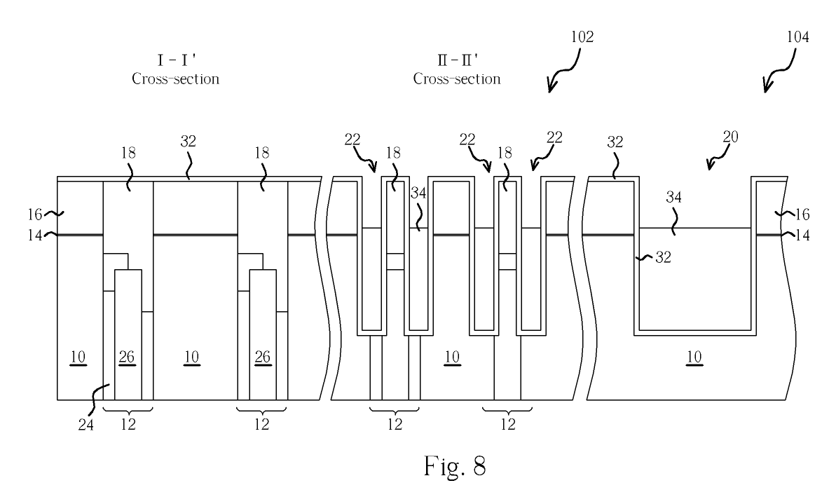

As shown in FIG. 8, using the silicon nitride liner 32 as an etching hard mask, a dry etching process is carried out to recess etch the remaining silicon oxide layer 34 to a predetermined depth inside the STI trenches 22 and 20, for example, 500-1100 angstroms. Preferably, after dry etching the top surface of the silicon oxide layer 34 inside the STI trenches 22 and 20 is lower than the top surface of the silicon nitride liner 32 32.

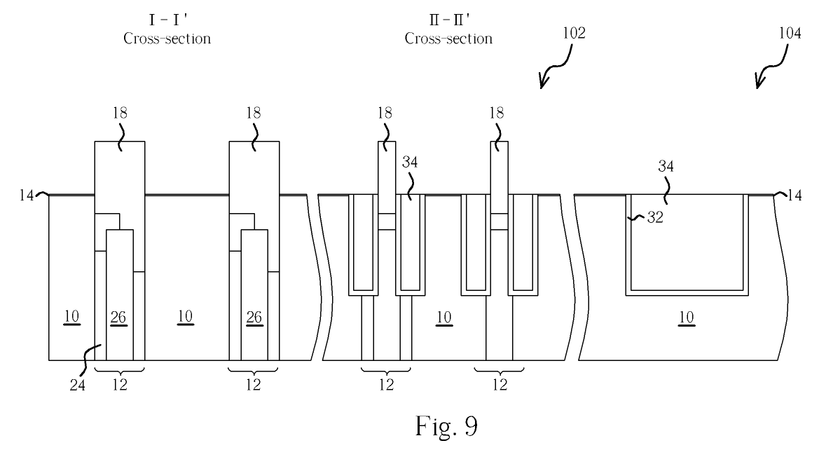

As shown in FIG. 9, the pad nitride layer 16 and the overlying silicon nitride liner 32 are stripped off from the surface of the semiconductor substrate 10 by using conventional etching methods such as wet etching involving the use of hot phosphoric acid solution, thereby exposing the pad oxide layer 14. After the removal of the pad nitride layer 16, the trench top oxide layer 18 protrudes from the main surface of the semiconductor substrate 10 with a height of about 150-1500 angstroms. An ion implantation process may be carried out to form doping regions of different conductivity types or ion wells (not shown) inside the semiconductor substrate 10.

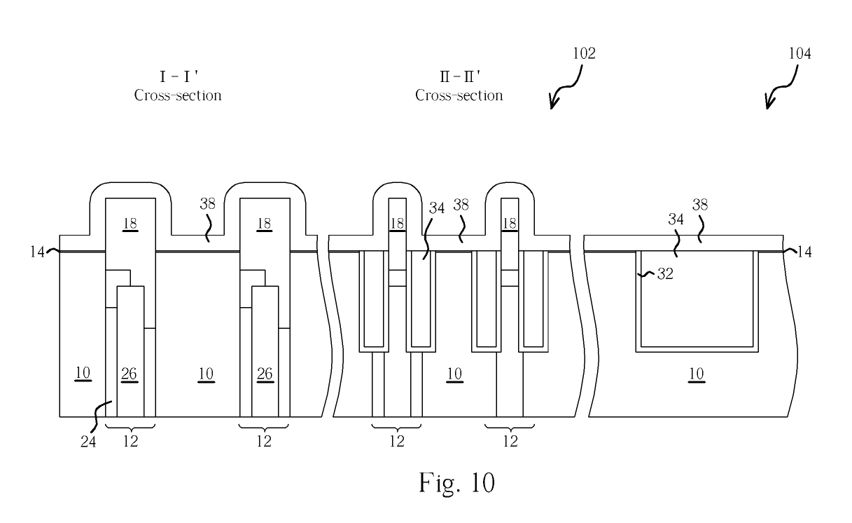

As shown in FIG. 10, a conformal spacer layer 38 is blanket deposited over the semiconductor substrate 10 and on the upward protruding trench top oxide layer 18. According to the preferred embodiments, the spacer layer 38 is a single layer of silicon nitride or a dual layer structure comprising silicon nitride and polysilicon.

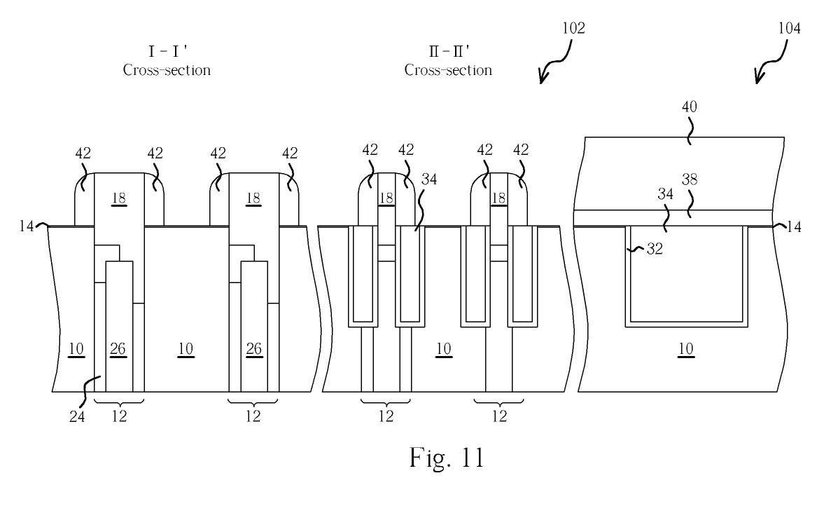

As shown in FIG. 11, a photolithographic process is performed to form a photoresist layer 40 that only masks the peripheral circuit area 104. The photoresist layer 40 protects the spacer layer 38 in the peripheral circuit area 104 but exposes the spacer layer 38 in the memory array area 102. Thereafter, using the photoresist layer 40 as an etching hard mask, a dry etching process is carried out to anisotropically etch the exposed spacer layer 38, thereby forming spacer 42 at sidewall of the upward protruding trench top oxide layer 18.

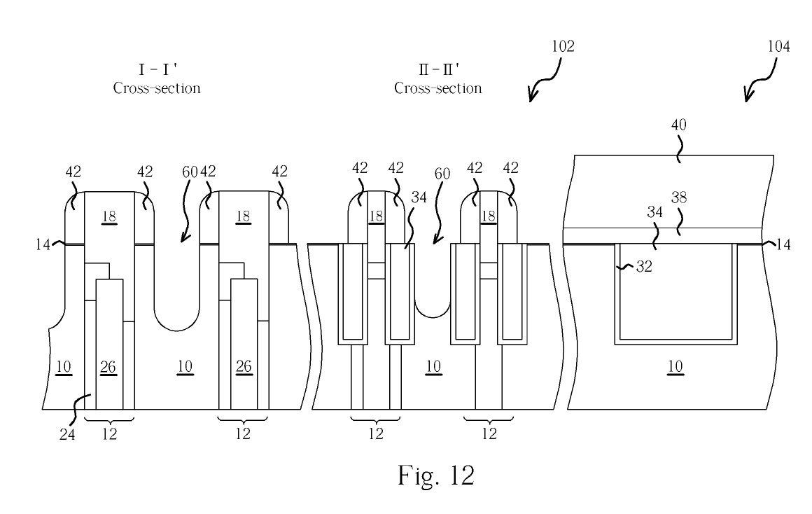

As shown in FIG. 12, after the formation of the spacer 42, another dry etching process is performed. Using the spacer 42, the trench top oxide layer 18 and the silicon oxide layer 34 inside the STI trenches 22 and 20 as etching hard mask, gate trench 60 between the deep trench capacitors 12 is etched into the pad oxide layer 14 and the semiconductor substrate 10 in a self aligned fashion.

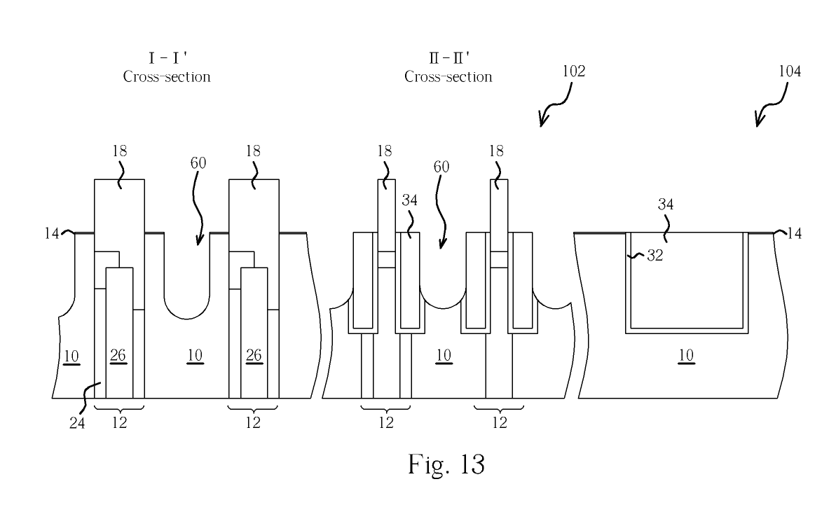

As shown in FIG. 13, after etching the gate trench 60, the photoresist layer 40 covering the peripheral circuit area 104 is removed. A wet etching process is performed to remove the spacer layer 38 in the peripheral circuit area 104 and the spacer 42 in the memory array area 102. Simultaneously, the exposed silicon nitride liner 32 inside the gate trench 60 is also removed.

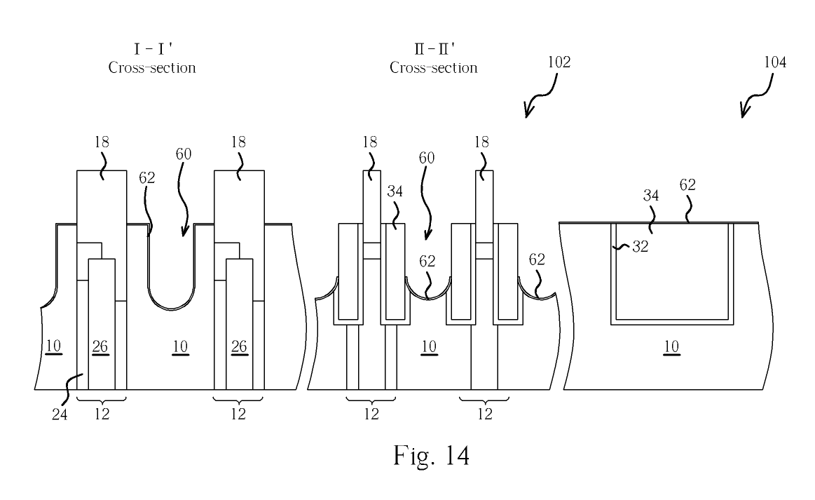

As shown in FIG. 14, after removing the spacer layer, another wet etching process is carried out to remove the pad oxide layer 14. A thermal oxidation process is performed to form a thick gate dielectric layer 62 on the exposed semiconductor substrate 10 and on the surface of the gate trench 60. The aforesaid thermal oxidation process may be In-Situ Steam Growth (ISSG) process, but not limited thereto.

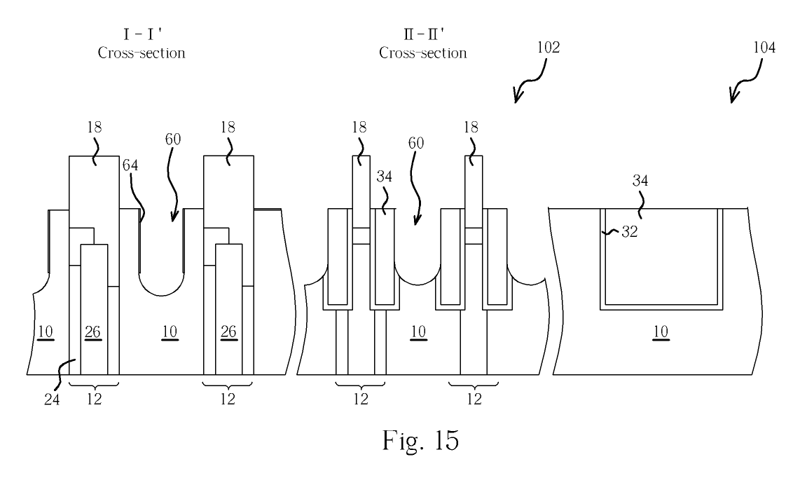

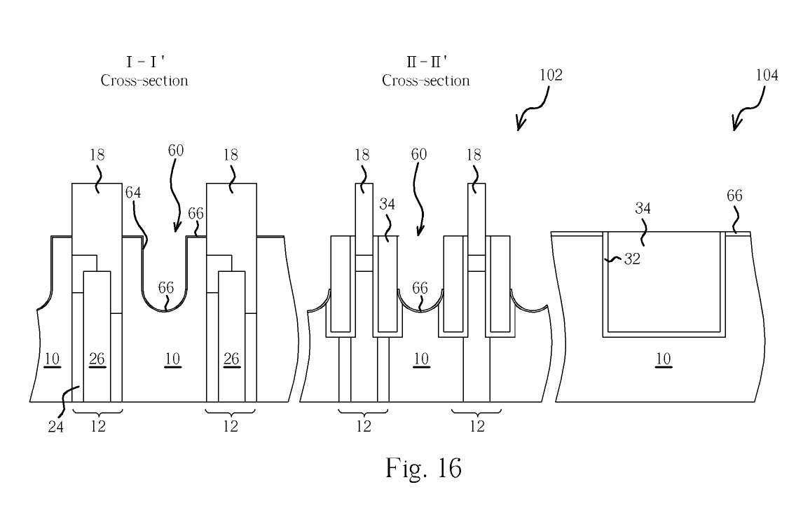

As shown in FIG. 15, an anisotropic dry etching process is carried out to etch the thick gate dielectric layer 62, thereby forming spacer 64 on the sidewall of the gate trench 60. Subsequently, another thermal oxidation process such as ISSG process is performed to form a thin gate dielectric layer 66 on the exposed semiconductor substrate 10 and at the bottom of the gate trench 60, as shown in FIG. 16. However, the gate dielectric layer 66 is not limited to oxide. For example, the gate dielectric layer 66 may be made of high-k dielectric materials.

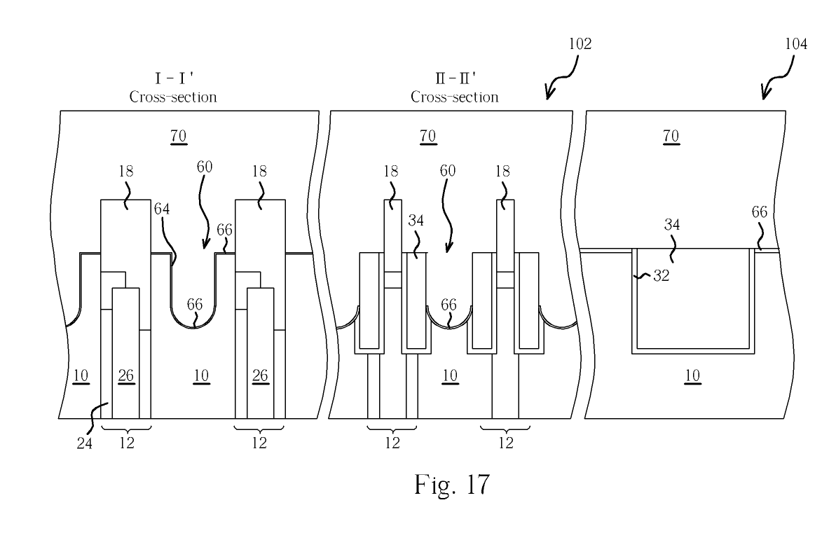

As shown in FIG. 17, a CVD process such as LPCVD or PECVD process is performed to deposit a polysilicon layer 70 over the semiconductor substrate 10 in the memory array area 102 and in the peripheral circuit area 104. The polysilicon layer 70 fills the gate trench 60. The polysilicon layer 70 may be made of metal gate materials such as W, TiN, HfN, Mo, or any combination thereof.

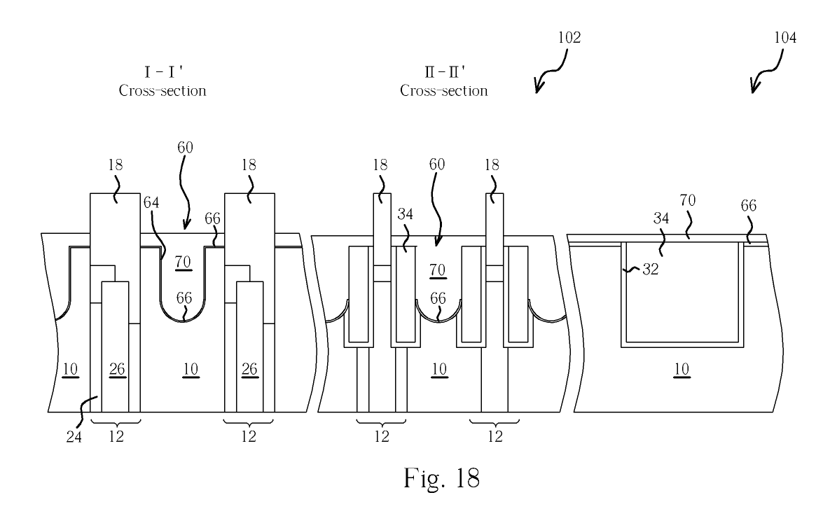

As shown in FIG. 18, the polysilicon layer 70 is etched back by using a dry etching method or wet etching process. After etching, the top surface of the polysilicon layer 70 is lower than the top surface of the trench top oxide layer 18. At this phase, except the upward protruding trench top oxide layer 18, the other area of the semiconductor substrate 10 including the memory array area 102 and the peripheral circuit area 104 is covered with the polysilicon layer 70.

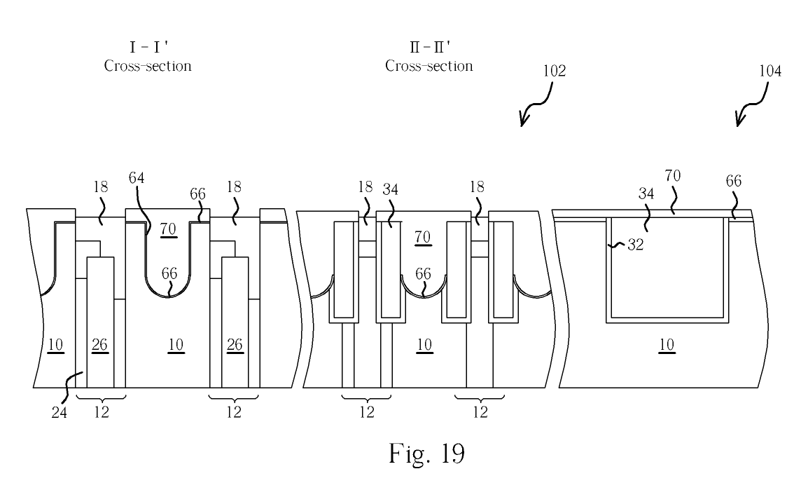

As shown in FIG. 19, after etching back the polysilicon layer 70, another wet process such as wet etching is performed to etch the trench top oxide layer 18 protruding from the surface of the polysilcion layer 70. For example, diluted hydrofluoric acid solution may be used to etch the trench top oxide layer 18. The remaining trench top oxide layer 18 has a top surface that is approximately coplanar with the main surface of the semiconductor substrate 10 (slightly lower than the top surface of the remaining polysilcion layer 70).

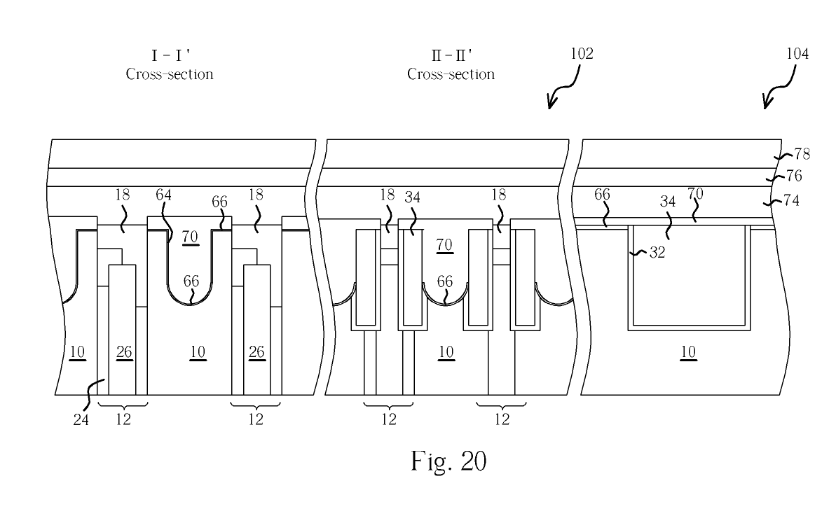

As shown in FIG. 20, after the etching of the trench top oxide layer 18, a polysilicon layer 74 is blanket deposited over the semiconductor substrate 10. A tungsten silicide layer 76 is then formed on the polysilicon layer 74. A silicon nitride cap layer 78 is then deposited on the tungsten silicide layer 76. The polysilicon layer 74 covers the polysilicon layer 70 and on the trench top oxide layer 18. Preferably, the polysilicon layer 74 has a thickness of about 200-900 angstroms. The tungsten silicide layer 76 has a thickness of about 100-800 angstroms. The silicon nitride cap layer 78 has a thickness of about 800-1500 angstroms.

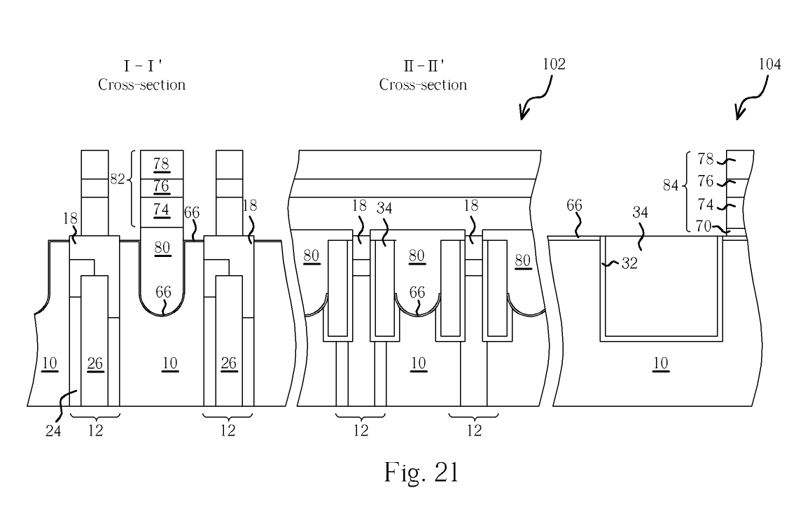

As shown in FIG. 21, subsequently, a photolithographic process and an etching process are performed. A photoresist mask (not shown) is used to define the gate conductor pattern within the memory array area 102 and the logic gate pattern within the peripheral circuit area 104. Using the photoresist mask as an etching hard mask, the silicon nitride cap layer 78, tungsten silicide layer 76 and the polysilicon layers 70 and 74 that are not covered by the photoresist mask are etched away, thereby forming recessed gate 80 and gate conductor 82 in the memory array area 102 and forming gate structure 84 in the peripheral circuit area 104.

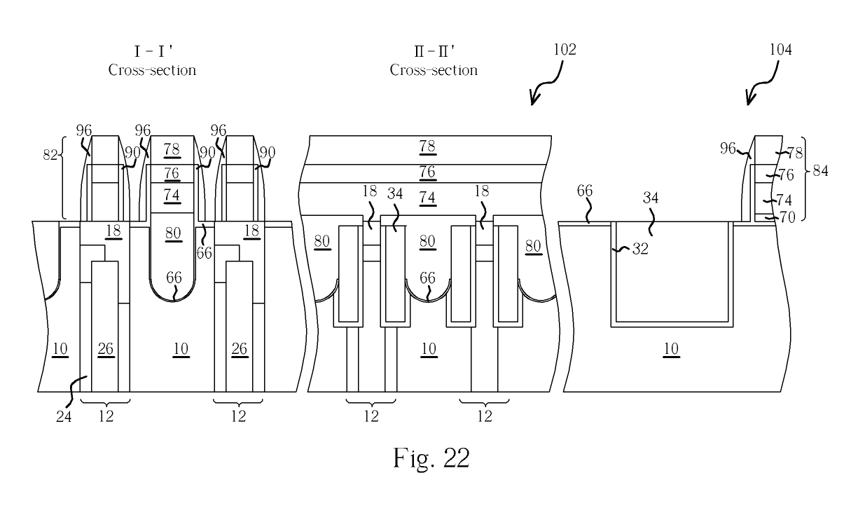

Finally, as shown in FIG. 22, after the patterning of the gates, a thermal oxidation process such as rapid thermal process (RTP) is performed to form insulation oxide 90 on respective sidewall of the gates including gate conductors 82 and the gate 84. After the formation of the insulation oxide 90, a spacer 96 is formed on sidewall of the gate conductors 82 and the gate 84.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a recessed gate MOS transistor device, comprising:
providing a semiconductor substrate having a main surface, wherein a pad layer is formed on said main surface;
forming a plurality of trench capacitors in said semiconductor substrate, wherein each said trench capacitor is capped with a trench top oxide layer, and wherein said trench top oxide layer has a top surface higher than said main surface;
performing a lithographic and etching process to form a plurality of isolation trenches in said semiconductor substrate;
depositing an insulation layer on said semiconductor substrate and in said isolation trenches, wherein said insulation layer fills said isolation trenches;
etching back said insulation layer such that a top surface of said insulation layer is lower than said top surface of said trench top oxide layer;
stripping said pad layer to expose said semiconductor substrate and said trench top oxide layer;
forming a spacer on sidewalls of said trench top oxide layer;
using said spacer as an etching hard mask, etching said semiconductor substrate to form a gate trench;
forming a gate dielectric layer on interior surface of said gate trench; and
forming a gate material layer on said gate dielectric layer, wherein said gate material layer fills said gate trench.

2. The method of claim 1 wherein said insulation layer comprises high-density plasma CVD (HDPCVD) oxide.

3. The method of claim 1 wherein said pad layer comprises silicon nitride and silicon oxide.

4. The method of claim 1 wherein before depositing an insulation layer on said semiconductor substrate, the method further comprises:
depositing a liner in said isolation trenches.

5. The method of claim 4 wherein said liner comprises silicon nitride.

6. The method of claim 1 wherein said spacer on sidewalls of said trench top oxide layer is formed by using an anisotropic dry etching process.
